(19) United States
(12) Patent Application Publication
(10) Pub. No.: US 2013/0137209 A1
(43) Pub. Date: May 30, 2013

(54) METHOD OF MANUFACTURING SOLAR CELL

(71) Applicant: SANYO ELECTRIC CO., LTD., Osaka (JP)

(72) Inventors: Hironobu Tsujimoto, Osaka (JP); Yayoi Santanda, Osaka (JP); Shinji Kobayashi, Osaka (JP); Tsuyoshi Takahama, Osaka (JP)

(73) Assignee: SANYO ELECTRIC CO., LTD., Osaka (JP)

(21) Appl. No.: 13/750,191

(22) Filed: Jan. 25, 2013

Related U.S. Application Data
(63) Continuation of application No. PCT/JP2011/066708, filed on Jul. 22, 2011.

(30) Foreign Application Priority Data
Jul. 30, 2010 (JP) 2010-171319

(51) Int. Cl. H01L 31/18

(52) U.S. Cl. CPC H01L 31/18
USPC 438/96

(57) ABSTRACT

A method of manufacturing a solar cell includes: forming an electrode on a first main surface of a photoelectric conversion body through screen printing; and then forming an electrode on a second main surface of the photoelectric conversion body, located on the opposite side from the first main surface, through screen printing, the photoelectric conversion body including a p- type or n-type semiconductor substrate and an amorphous silicon layer stacked on one surface of the semiconductor substrate on the first main surface side and having the opposite conductivity from the semiconductor substrate, such that the first main surface of the photoelectric conversion body comprises a pn junction.

### CROSS REFERENCE TO RELATED APPLICATIONS

This application is a continuation application of International Application No. PCT/JP2011/066708, filed on Jul. 22, 2011, entitled “METHOD OF MANUFACTURING SOLAR CELL MODULE”, which claims priority based on Article 8 of Patent Cooperation Treaty from prior Japanese Patent Applications No. 2010-171319, filed on Jul. 30, 2010, the entire contents of which are incorporated herein by reference.

### BACKGROUND OF THE INVENTION

1. Field of the Invention

This disclosure relates to a method of manufacturing a solar cell and relates particularly to a method of manufacturing a solar cell which uses screen printing to provide electrodes to the solar cell.

2. Description of Related Art

For forming electrodes in a solar cell, screen printing is often used because it offers good productivity, reliability, and so on. A solar cell in which finger electrodes are formed on both the light-receiving surface and the opposite surface by using silver paste through screen printing has been known (see Patent Document 1: Japanese Patent Application Publication No. 2005-252108, for example).

Meanwhile, there has been known a solar cell with a structure in which a substantially intrinsic amorphous semiconductor is sandwiched between a crystalline semiconductor substrate and an amorphous semiconductor to reduce defects at the interface and thereby improve properties of the heterojunction interface.

In a solar cell with this structure, too, screen printing has been used to form electrodes.

### SUMMARY OF THE INVENTION

Here, there has been an increasing demand for higher performance solar cells along with the popularization of solar cells. Such a demand is creating a need for improvement in the performance of solar cells through improvement of electrode formation steps.

An object of an embodiment of the invention is to provide a high performance solar cell by improving electrode formation steps.

An aspect of the invention is a method of manufacturing a solar cell. The method includes: forming an electrode on a first main surface of a photoelectric conversion body through screen printing; and then forming an electrode on a second main surface of the photoelectric conversion body, located on the opposite side from the first main surface, through screen printing. The photoelectric conversion body includes a p- or n-type semiconductor substrate and an amorphous silicon layer stacked on one surface of the semiconductor substrate and having the opposite conductivity from the semiconductor substrate, such that the first main surface of the photoelectric conversion body comprises a pn junction.

According to the aspect of the invention, it is possible to obtain a high performance solar cell.

### BRIEF DESCRIPTION OF THE DRAWINGS

FIG. 1 is a cross-sectional view showing the configuration of a solar cell according to an embodiment of the invention.

FIG. 2A is a cross-sectional view showing a method for forming the solar cell according to the embodiment step by step.

FIG. 2B is a cross-sectional view showing the method for forming the solar cell according to the embodiment step by step.

FIG. 2C is a cross-sectional view showing the method for forming the solar cell according to the embodiment step by step.

FIG. 2D is a cross-sectional view showing the method for forming the solar cell according to the embodiment step by step.

FIG. 2E is a cross-sectional view showing the method for forming the solar cell according to the embodiment step by step.

FIG. 3 is a schematic cross-sectional view showing a screen printing step on one surface of the solar cell according to the embodiment.

FIG. 4 is a schematic cross-sectional view showing a screen printing step on the other surface of the solar cell according to the embodiment.

FIG. 5A is a cross-sectional view showing a method for forming a solar cell according to a comparative example step by step.

FIG. 5B is a cross-sectional view showing the method for forming the solar cell according to the comparative example step by step.

FIG. 6 is a schematic cross-sectional view showing a screen printing step on one surface of the solar cell according to the comparative example.

FIG. 7 is a schematic cross-sectional view showing a screen printing step on the other surface of the solar cell according to the comparative example.

FIG. 8 is a cross-sectional view showing the configuration of a solar cell according to another embodiment of the invention.

FIG. 9A is a cross-sectional view showing a method for forming the solar cell according to the other embodiment step by step.

FIG. 9B is a cross-sectional view showing the method for forming the solar cell according to the other embodiment step by step.

FIG. 9C is a cross-sectional view showing the method for forming the solar cell according to the other embodiment step by step.

FIG. 9D is a cross-sectional view showing the method for forming the solar cell according to the other embodiment step by step.

FIG. 9E is a cross-sectional view showing the method for forming the solar cell according to the other embodiment step by step.

FIG. 10 is a schematic cross-sectional view showing a screen printing step on one surface of the solar cell according to the other embodiment.

FIG. 11 is a schematic cross-sectional view showing a screen printing step on the other surface of the solar cell according to the other embodiment.

FIG. 12 is a graph of characteristic comparison between the embodiment and the comparative example.

### DETAILED DESCRIPTION OF EMBODIMENTS

Embodiments of the invention are described in detail with reference to the drawings. Note that in the drawings, the same or equivalent portions are designated by the same reference numerals, and descriptions thereof are not repeated to avoid duplicate explanations. Here, it should be noted that the drawings are schematic and that dimensional ratios and the like may be different from the actual ones. Accordingly, specific dimensions and the like should be determined in consideration of the following descriptions. In addition, some drawings may include portions which differ from one drawing to another in terms of the dimensional relationship and ratio, as a matter of course.

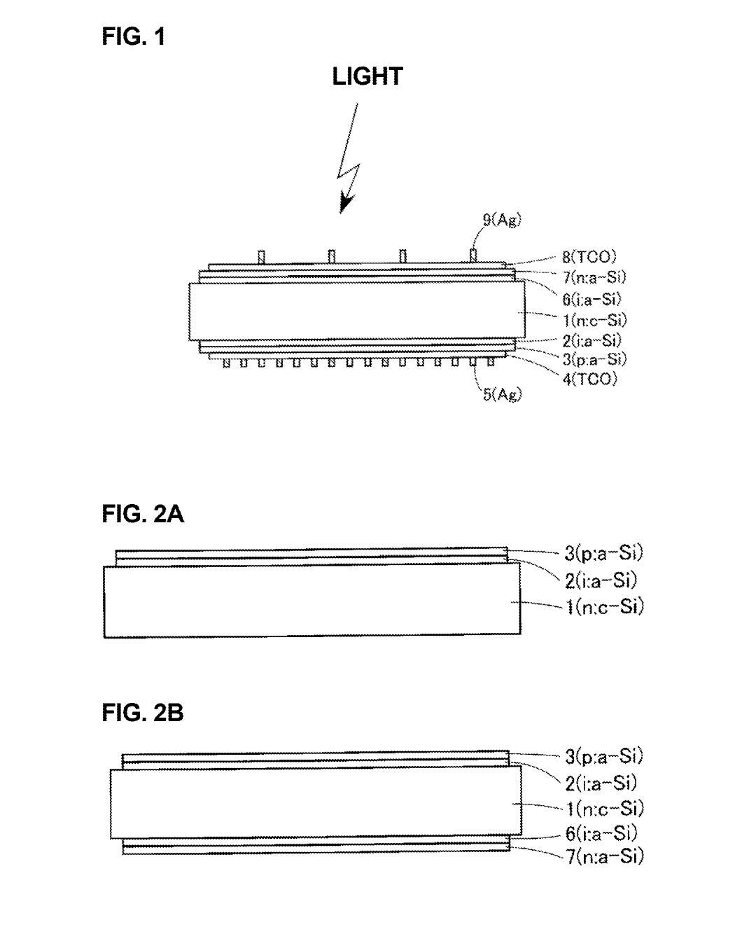

FIG. 1 is a cross-sectional view showing the configuration of a solar cell according to an embodiment. The configuration of the solar cell according to the embodiment is described with reference to FIG. 1.

The solar cell according to the embodiment employs a structure in which a substantially intrinsic amorphous semiconductor is sandwiched between a crystalline semiconductor substrate and an amorphous semiconductor. This structure reduces defects at the interface and prevents recombination of minority carriers at the heterojunction interface.

As shown in FIG. 1, the solar cell includes: a photoelectric conversion body (1, 2, 3, 4, 6, 7, and 8) including n-type single crystal silicon substrate 1, i-type amorphous silicon layer 2, p-type amorphous silicon layer 3, transparent conductive film 4, i-type amorphous silicon layer 6, n-type amorphous silicon layer 7, and transparent conductive film 8; electrodes 5 formed on one surface of the photoelectric conversion body; and electrodes 9 formed on the other surface of the photoelectric conversion body. Details are described below.

The photoelectric conversion body (1, 2, 3, 4, 6, 7, and 8) includes n-type single crystal silicon substrate (n: c-Si) 1 having a resistivity of approximately 1 Ω·cm and a thickness of approximately 200 μm and also having a (100) plane. A texture structure formed of pyramid-shaped asperities measuring several pm to several tens of pm in height is formed on one or both surfaces of n-type single crystal silicon substrate 1. Substantially i-type amorphous silicon layer (i: a-Si) 2 having a thickness of approximately 5 nm is formed on one surface (lower surface in FIG. 1) of this n-type single crystal silicon substrate 1. Moreover, p-type amorphous silicon layer (p: a-Si) 3 having a thickness of approximately 5 nm is formed on i-type amorphous silicon layer 2. By this configuration, the one surface (lower surface in FIG. 1) of n-type single crystal silicon substrate 1 has a pn junction that serves for power generation.

Moreover, transparent conductive film (TCO) 4 having a thickness of approximately 100 nm is formed on p-type amorphous silicon layer 3 on the one surface (lower surface in FIG. 1) of n-type single crystal silicon substrate 1. This transparent conductive film 4 is formed of a transparent conductive oxide film of indium tin oxide, zinc oxide, or the like.

Further, electrodes 5 are formed in a predetermined region on transparent conductive film 4 on the one surface (lower surface in FIG. 1) of n-type single crystal silicon substrate 1. These electrodes 5 are formed by using a conductive paste such as silver (Ag) paste. Moreover, electrodes 5 are formed of finger electrode portions and a bus-bar electrode portion.

On the other hand, substantially i-type amorphous silicon layer 6 having a thickness of approximately 5 nm is formed on the other surface (upper surface in FIG. 1) of n-type single crystal silicon substrate 1. N-type amorphous silicon layer 7 having a thickness of approximately 20 nm is formed on i-type amorphous silicon layer 6. Moreover, transparent conductive film 8 having a thickness of approximately 100 nm is formed on n-type amorphous silicon layer 7. Electrodes 9 are formed in a predetermined region on transparent conductive film 8.

As shown in FIG. 1, the solar cell in the embodiment has a structure in which the pn junction serving for power generation is located on the opposite side (lower surface side in FIG. 1) to the light-receiving surface (hereinafter, referred to as “BS structure”). Light enters the solar cell mainly from its light-receiving surface side (upper surface side in FIG. 1). To reduce the amount of light blocked at the light-receiving surface of the solar cell, more finger electrodes are given to electrodes 5 provided on the opposite side (p-type amorphous silicon layer 3 side) to the light-receiving surface of the solar cell where the amount of incident light is smaller, whereas fewer finger electrodes are given to electrodes 9 provided on the light-receiving surface side (n-type amorphous silicon layer 7 side) of the solar cell where the amount of incident light is larger.

For example, electrodes 5 on the opposite side (p-type amorphous silicon layer 3 side) to the light-receiving surface of the solar cell have 221 finger electrodes, whereas electrodes 9 on the light-receiving surface side (n-type amorphous silicon layer 7 side) of the solar cell have 61 finger electrodes. Thus, the number of the finger electrodes of electrodes 5 on the opposite side to the light-receiving surface of the solar cell is about four times more than the light-receiving surface of the solar cell.

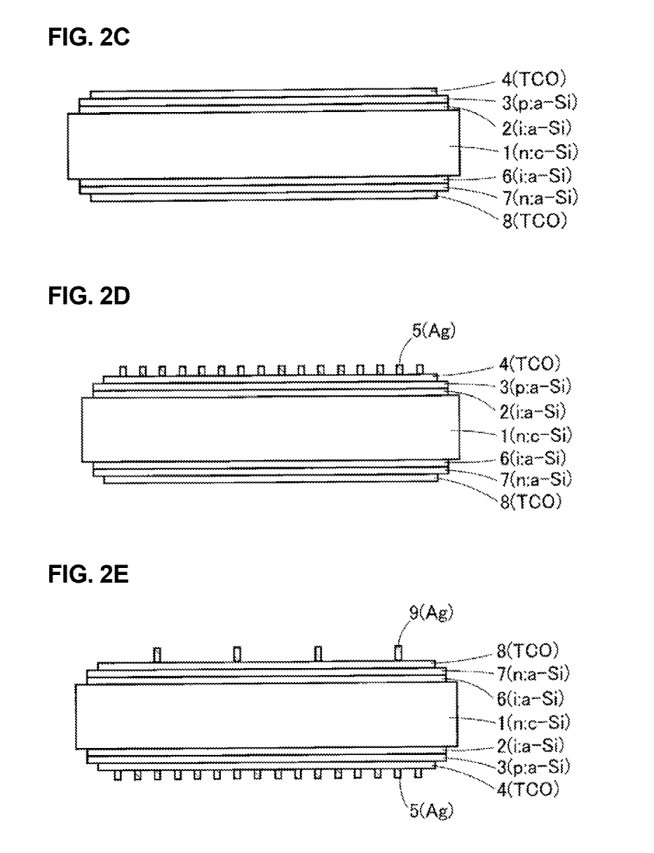

Next, a method of manufacturing the solar cell shown in FIG. 1 is described with reference to FIGS. 2A to 2E, 3, and 4.

As shown in FIG. 2A, first, n-type single crystal silicon substrate 1 having a (100) plane is prepared. This n-type single crystal silicon substrate 1 is etched to form pyramid-shaped asperities in both surfaces of the substrate. Then, i-type amorphous silicon layer 2 and p-type amorphous silicon layer 3 are formed on the aforementioned one surface (upper surface in FIG. 2A) of this n-type single crystal silicon substrate 1. I-type amorphous silicon layer 2 and p-type amorphous silicon layer 3 are formed through CVD such as plasma CVD, for example.

Subsequently, as shown in FIG. 2B, i-type amorphous silicon layer 6 and n-type amorphous silicon layer 7 are formed on the other surface (upper surface in FIG. 2B) of n-type single crystal silicon substrate 1. I-type amorphous silicon layer 6 and n-type amorphous silicon layer 7 are formed through CVD such as plasma CVD, for example.

Thereafter, as shown in FIG. 2C, transparent conductive films 4 and 8 having a thickness of approximately 100 nm are formed on p-type amorphous silicon layer 3 on the one surface and n-type amorphous silicon layer 7 on the other surface, respectively. Transparent conductive films 4 and 8 are formed through sputtering using indium oxide, for example. By the above steps, obtained is a photoelectric conversion body including n-type single crystal silicon substrate 1, i-type amorphous silicon layer 2, p-type amorphous silicon layer 3, transparent conductive film 4, i-type amorphous silicon layer 6, n-type amorphous silicon layer 7, and transparent conductive film 8. Specifically, a pn junction serving for power generation is located in a first main surface (upper surface in FIG. 2C) of the photoelectric conversion body, which is, in the embodiment, a side where p-type amorphous silicon layer 3 is provided, and no pn junction is given in a second main surface (lower surface in FIG. 2C) of the photoelectric conversion body on the opposite side to the first main surface.

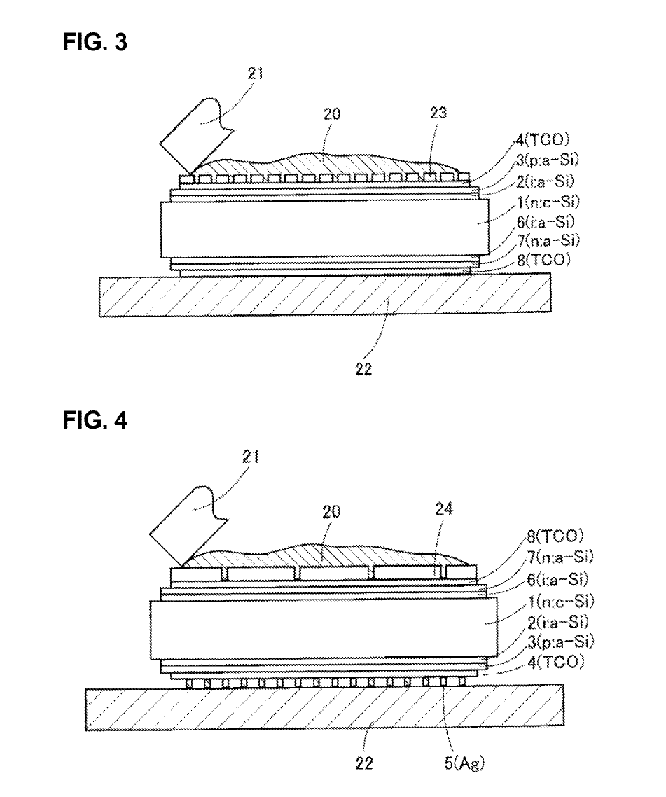

Then, electrodes 5 are formed through screen printing using silver paste in a predetermined region on the first main surface of the photoelectric conversion body having the pn junction which serves for power generation (i.e. the upper surface of transparent conductive film 4 on p-type amorphous silicon layer 3 in FIG. 2D). The method for forming electrodes 5 is as shown in FIG. 3. First, n-type single crystal silicon substrate 1 is mounted on print stage 22 with the second main surface (n-type amorphous silicon layer 7 side) of the photoelectric conversion body facing down so that the second main surface may be in contact with print stage 22. Then, screen mask 23 formed in a predetermined pattern for forming the electrodes is arranged on the first main surface (p-type amorphous silicon layer 3 side) facing up. Thereafter, conductive paste 20, which will become the electrodes, is loaded on screen mask 23 and, with given squeegee 21, filled into openings provided in screen mask 23. After filling conductive paste 20, screen mask 23 is removed, whereby electrodes 5 are formed on transparent conductive film 4 in the first main surface.

Subsequently, electrodes 9 are formed through screen printing using the conductive paste in a predetermined region on the second main surface of the photoelectric conversion body (i.e. the upper surface of transparent conductive film 8 in FIG. 2E). The method for forming electrodes 9 is as shown in FIG. 4. First, n-type single crystal silicon substrate 1 is mounted on print stage 22 with the second main surface (n-type amorphous silicon layer 7 side) of the photoelectric conversion body facing up, or with the first main surface of the photoelectric conversion body (the surface on which electrodes 5 are formed) facing down, so that electrodes 5 may be in contact with print stage 22. Then, screen mask 24 formed in a predetermined pattern for forming the electrodes are arranged on the second main surface (n-type amorphous silicon layer 7 side) facing up. Here, in the screen printing step, the first main surface having the pn junction is supported on print stage 22 through electrodes 5. Thereafter, conductive paste 20, which will become the electrodes, is loaded on screen mask 24 and, with given squeegee 21, filled into openings provided in screen mask 24. After filling conductive paste 20, screen mask 24 is removed, whereby electrodes 9 are formed on transparent conductive film 8 in the second main surface.

As a result, the solar cell according to the embodiment is obtained. As can be seen from above, according to the embodiment, the pn junction is not damaged when the electrodes are formed through screen printing. Hence, a solar cell with a high output characteristic can be obtained.

To be more specific, in the screen printing step shown in FIG. 2D, the first main surface having the pn junction, which serves for power generation, does not contact print stage 22. This eliminates the possibility of damaging the pn junction due to displacement, rubbing, etc. of the substrate. Thus, adverse effects such as breakage of the pn junction can be prevented. Thereafter, in the screen printing step shown in FIG. 2E, the first main surface having the pn junction is supported on print stage 22 through electrodes 5. This eliminates the possibility of direct contact between print stage 22 and the first main surface having the pn junction, which serves for power generation. Thus, damage to the pn junction can be reduced. Moreover, the number of electrodes 5 formed first is larger than the number of electrodes 9 formed later. Thus, the pressure exerted on substrate 1 in the screen printing step for forming electrodes 9 is dispersed, thus reducing damage to the pn junction accordingly.

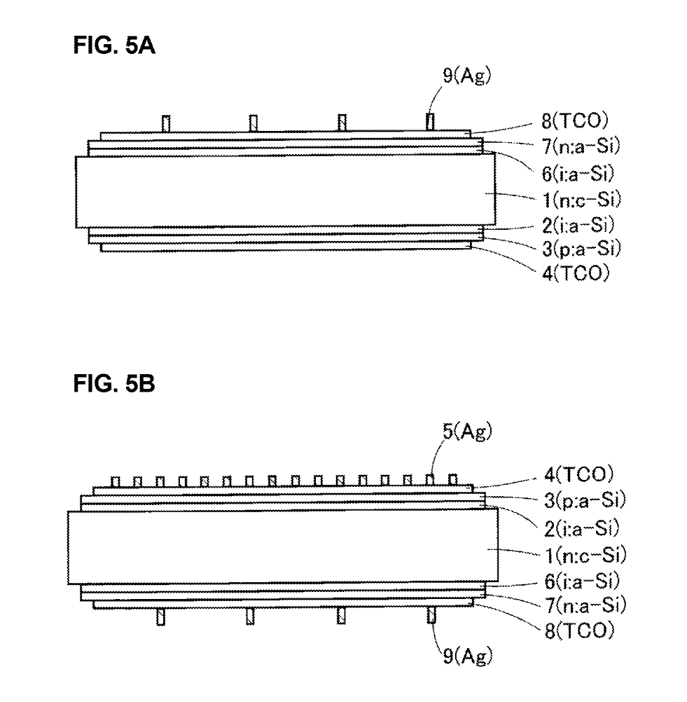

Next, a solar cell according to a comparative example is described with reference to FIGS. 5A, 5B, 6, and 7. This comparative example forms electrodes 5 and 9 through screen printing as in the embodiment but differs from the embodiment in the order of forming electrodes 5 and 9. Specifically, in the comparative example, electrodes 9 on the second main surface (n-type amorphous silicon layer 7 side) having no pn junction are formed first. Note that in FIG. 5A, the surface which is located on the lower side of n-type single crystal silicon substrate 1 and in which p-type amorphous silicon layer 3 is formed is the first main surface having the pn junction, while the surface which is located on the opposite side (upper surface) is the second main surface having no pn junction. In a method for forming the solar cell according to the comparative example, the solar cell is formed in the same way as the foregoing embodiment up to the formation of transparent conductive films 4 and 8.

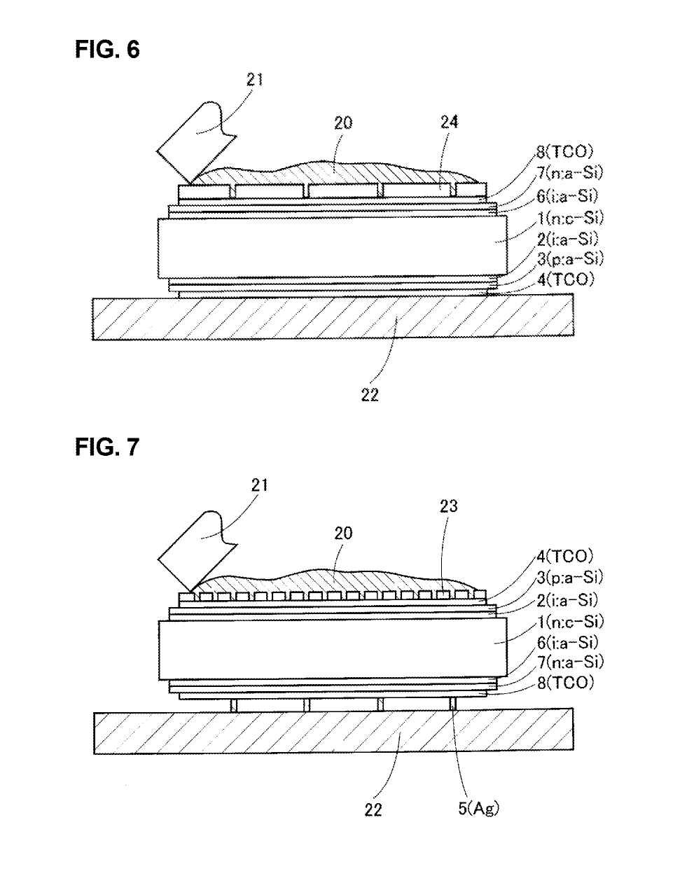

Then, as shown in FIG. 5A, electrodes 9 are formed on the second main surface having no pn junction through screen printing using conductive paste. As shown in FIG. 6, electrodes 9 are formed by: mounting n-type single crystal silicon substrate 1 on print stage 22 with the first main surface, which has the pn junction (the surface in which p-type amorphous silicon layer 3 is provided), facing down; and then forming electrodes 9 on transparent conductive film 8 in the second main surface, which has no pn junction, in the same manner as the step in FIG. 2E.

Subsequently, as shown in FIG. 5B, electrodes 5 are formed through screen printing using the conductive paste in a predetermined region on transparent conductive film 4 in the first main surface having the pn junction. As shown in FIG. 7, electrodes 5 are formed by: mounting n-type single crystal silicon substrate 1 on print stage 22 with the second main surface, which has no pn junction (the surface on which electrodes 9 are formed), facing down so that electrodes 9 maybe in contact with print stage 22; and then forming electrodes 5 on transparent conductive film 4 in the first main surface, which has the pn junction, in the same manner as the step in FIG. 2D.

As a result, the solar cell according to the comparative example is obtained.

Of the screen printing steps of the comparative example, the step in FIG. 5A may possibly damage the pn junction and cause breakage of the pn junction or the like because the first main surface (lower surface in FIG. 5A) having the pn junction, which serves for power generation, comes into contact with print stage 22.

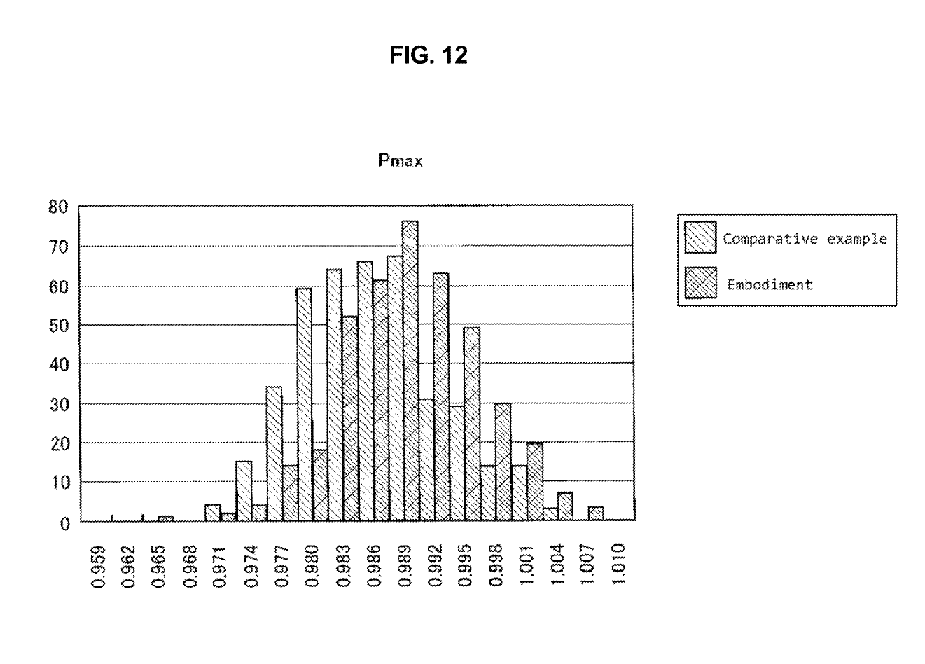

Next, solar cells according to the embodiment and solar cells according to the comparative are prepared, and their solar-cell characteristic is measured. FIG. 12 shows the result of the measurement. In FIG. 12, the vertical axis is the number of samples, while the horizontal axis is the solar-cell characteristic. Note that the value of the horizontal axis is one that is standardized with the characteristic of a solar cell according to the comparative example that is prepared in a good printing environment, that is, by using brand-new screen masks for both surfaces just after print stage 22 is cleaned.

For the compared samples, solar cells are prepared in a state where 500 shots of printing are performed after print stage 22 is cleaned. Note that one shot of printing refers to the operation shown in FIG. 3. Specifically, one shot of printing refers to a series of operations including: mounting n-type single crystal silicon substrate 1 on print stage 22; arranging screen mask 23 on the surface of n-type single crystal silicon substrate 1; loading conductive paste 20 on screen mask 23; and filling conductive paste 20 into the openings provided in screen mask 23.

As shown in FIG. 12, samples with high solar-cell characteristics are obtained more from the solar cell according to the embodiment than from the solar cell according to the comparative example. Specifically, the horizontal axis in FIG. 12 indicates the maximum value of the output power of a solar cell (Pmax) while the vertical axis indicates the number of samples corresponding to the Pmax value. Given that Pmax value of 0.989 where the largest number of samples exist is a reference, the total number of samples of the solar cell whose Pmax values are higher than the reference (Pmax value of 0.989) according to the embodiment is greater than the total number of samples of the solar cells whose Pmax values are higher than the reference (Pmax value of 0.989) according to the comparative example. This shows that, in the case of the solar cell according to the embodiment, damage caused to the pn junction when the electrodes are formed through screen printing is reduced, and therefore a solar cell with a high output characteristic can be obtained.

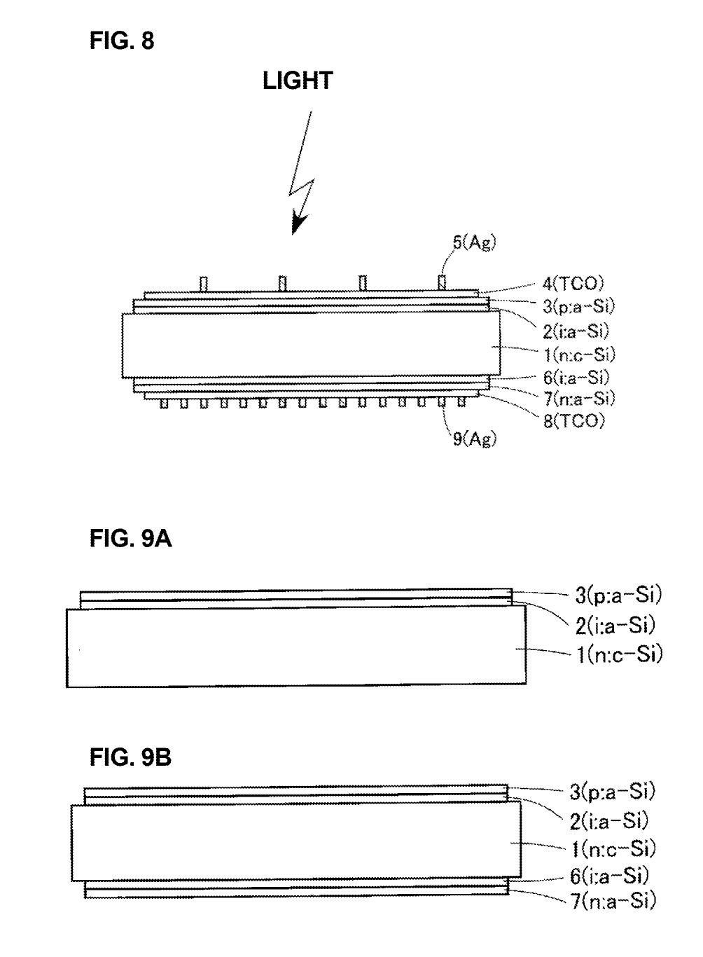

Next, another embodiment is described based on FIGS. 8, 9A to 9E, 10, and 11. FIG. 8 shows a structure in which light falls on a first main surface (upper surface in FIG. 8) with a pn junction formed therein (hereinafter, referred to as “STD structure”) and to which the invention is applied. Note that in FIG. 8, the surface which is located on the lower side of n-type single crystal silicon substrate 1 and in which n-type amorphous silicon layer 7 is formed is a second main surface having no pn junction, while the surface which is located on the opposite side (upper side) is the first main surface having the pn junction.

As shown in FIG. 8, substantially intrinsic i-type amorphous silicon layer 2 is formed on one surface (upper surface in FIG. 8) of n-type single crystal silicon substrate 1. P-type amorphous silicon layer 3 is formed on i-type amorphous silicon layer 2. Transparent conductive film 4 as a transparent conductive film is formed on p-type amorphous silicon layer 3. Electrodes 5 are formed in a predetermined region on the upper surface of this transparent conductive film 4.

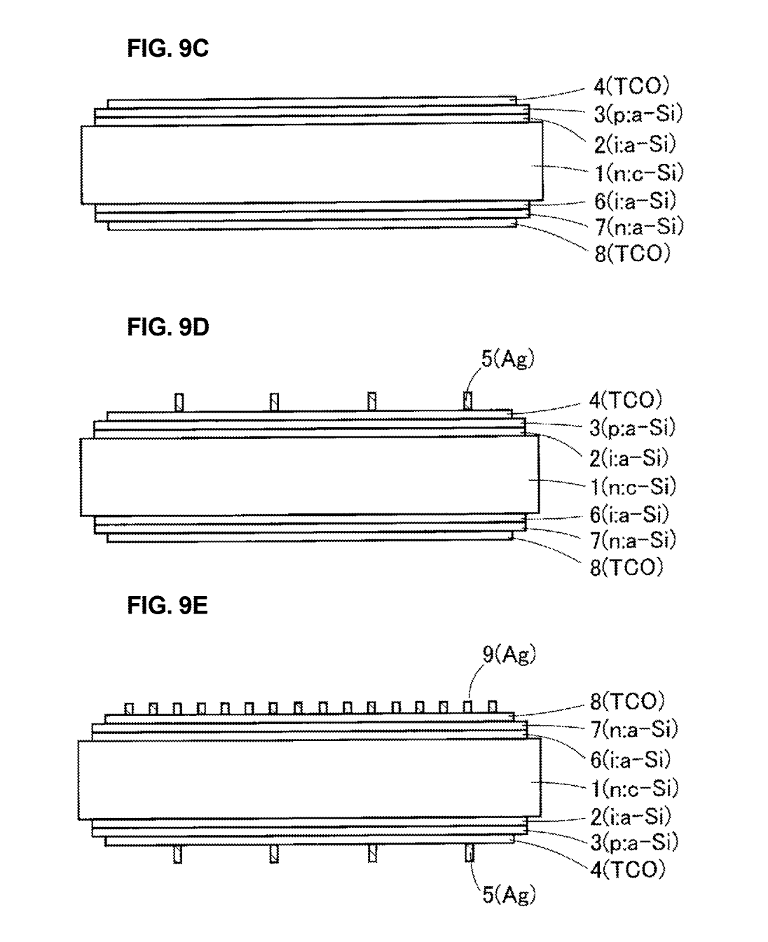

Moreover, substantially intrinsic i-type amorphous silicon layer 6 is formed on the other surface (lower surface in FIGS. 9A to 9D) of n-type single crystal silicon substrate 1. N-type amorphous silicon layer 7 is formed on i-type amorphous silicon layer 6. Transparent conductive film 8 is formed on n-type amorphous silicon layer 7. Electrodes 9 are formed in a predetermined region on transparent conductive film 8. By forming i-type amorphous silicon layer 6 and n-type amorphous silicon layer 7 in this order on the other surface of n-type single crystal silicon substrate 1 as described above, a so-called BSF structure is formed. The thicknesses of the films according to the other embodiment are the same as the thicknesses of the films of the solar cell according to the foregoing embodiment.

Next, a method of manufacturing the solar cell according the other embodiment is described with reference to FIGS. 9A to 9E, 10, and 11.

Steps in FIGS. 9A to 9C are the same as those in FIGS. 2A to 2C described above, and thus explanations thereof are omitted here by simply presenting the same reference numerals.

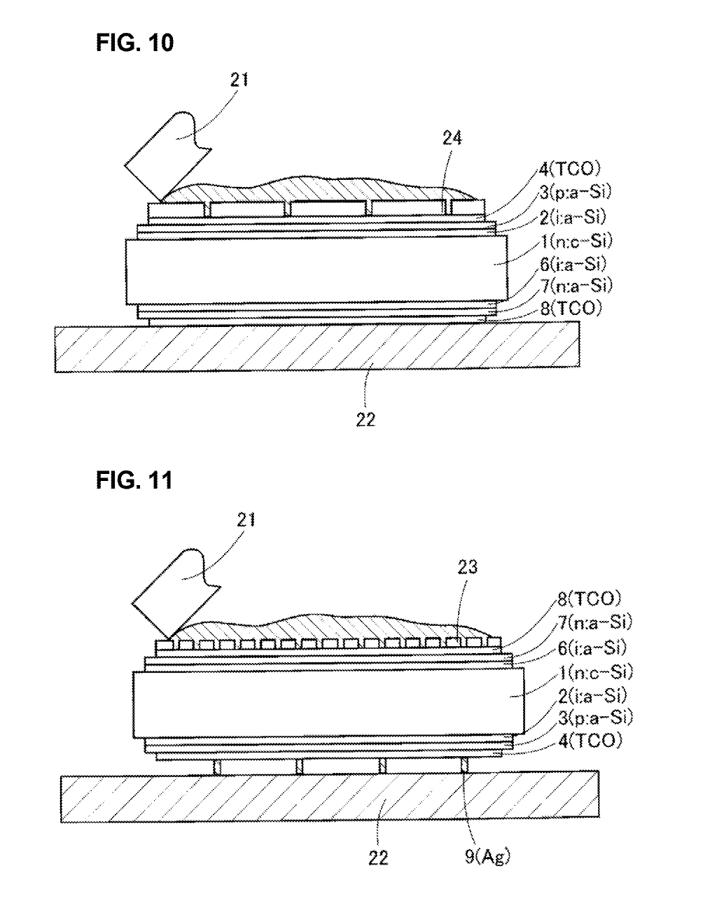

As shown in FIG. 9D, electrodes 5 are formed through screen printing using conductive paste in a predetermined region on the first main surface having the pn junction which serves for power generation (i.e. the upper surface of transparent conductive film 4 on p-type amorphous silicon layer 3). As shown in FIG. 10, the method for forming electrodes 5 includes: downwardly orienting the second main surface having no pn junction (the side in which n-type amorphous silicon layer 7 is provided) and mounting the second main surface on print stage 22; and then forming electrodes 5 on transparent conductive film 4 in the first main surface having the pn junction in the same manner as the step in FIG. 2E.

Subsequently, as shown in FIG. 9E, electrodes 9 are formed through screen printing using the conductive paste in a predetermined region on transparent conductive film 8 in the second main surface having no pn junction. As shown in FIG. 11, the method for forming electrodes 9 includes: mounting substrate 1 on print stage 22 with the first main surface, which has the pn junction (the surface on which electrodes 5 are formed), facing down so that electrodes 5 on the first main surface may be in contact with print stage 22; and then forming electrodes 9 on transparent conductive film 8 in the second main surface, which has no pn junction, in the same manner as the step in FIG. 2D.

As can be seen from above, according to the other embodiment, the pn junction is not damaged when the electrodes are formed through screen printing. Hence, a solar cell with a high output characteristic can be obtained.

Note that the steps shown in FIGS. 2A to 2E and the steps shown in FIGS. 9A to 9E differ in the number of electrodes formed above p-type amorphous silicon layer 3. The number of electrodes formed above p-type amorphous silicon layer 3 is greater in the solar cell with the BS structure than in the solar cell for the STD structure and is approximately four times greater in this embodiment. As a result, in the formation of the electrodes on the second main surface having no pn junction (n-type amorphous silicon layer 7 side), the pressure applied to the pn junction is dispersed to a greater extent in the solar cell with the BS structure than in the other. Accordingly, the effect of reducing damage to the pn junction can be expected to be greater than that of the solar cell with STD structure.

It should be understood that all the features of the embodiments disclosed herein are given for illustrative purposes only, and not for restrictive purposes. The scope of the invention is shown not by the descriptions of the embodiments given above but by the claims, and is intended to include all changes which come within the meaning and range of equivalency of the claims.

For example, the invention is applicable to a crystalline solar cell in which a pn junction is formed by using thermal diffusion. Moreover, the invention is applicable to a crystalline solar cell formed by using a p-type semiconductor substrate (silicon substrate).

1. A method of manufacturing a solar cell comprising:
forming an electrode on a first main surface of a photoelectric conversion body through screen printing; and
then forming an electrode on a second main surface of the photoelectric conversion body, located on the opposite side from the first main surface, through screen printing, the photoelectric conversion body including a p- or n-type semiconductor substrate and an amorphous silicon layer stacked on one surface of the semiconductor substrate on the first main surface side and having the opposite conductivity from the semiconductor substrate, such that the first main surface of the photoelectric conversion body comprises a pn junction.

2. The method of manufacturing a solar cell according to claim 1, wherein
the electrode on the first main surface includes a bus-bar electrode and finger electrodes connected to the bus-bar electrode , while the electrode on the second main surface includes a bus-bar electrode and finger electrodes connected to the bus-bar electrode on the second main surface, and
the number of the finger electrodes on the first main surface is different from the number of the finger electrodes on the second main surface.

3. The method of manufacturing a solar cell according to claim 2, wherein the number of the finger electrodes on the first main surface is greater than the number of the finger electrodes on the second main surface.

4. The method of manufacturing a solar cell according to claim 1, wherein the semiconductor substrate is a crystalline silicon substrate.

5. A method of manufacturing a solar cell comprising:
forming an electrode on a first main surface of a photoelectric conversion body through screen printing; and
then forming an electrode on a second main surface of the photoelectric conversion body, located on the opposite side from the first main surface, through screen printing, the photoelectric conversion body including a p- or n-type semiconductor substrate and an amorphous silicon layer stacked on one surface of the semiconductor substrate such that the first main surface of the photoelectric conversion body comprises a pn junction.

6. The method of manufacturing a solar cell according to claim 5, wherein the amorphous silicon layer is on the first main surface side and having the opposite conductivity from the semiconductor substrate.

7. The method of manufacturing a solar cell according to claim 5, wherein the amorphous silicon layer is on the second main surface side and having the same conductivity as the semiconductor substrate.
